(19) United States
(12) Patent Application Publication
(10) Pub. No.: US 2025/0144763 A1
(43) Pub. Date: May 8, 2025

(54) POLISHING PAD AND PROCESS FOR PREPARING THE SAME

(71) Applicant: SK enpulse Co., Ltd., Gyeonggi-do (KR)

(72) Inventors: Younghwan KIM, Gyeonggi-do (KR); Jangwon SEO, Gyeonggi-do (KR); Jongwook YOON, Gyeonggi-do (KR); Eungi MIN, Gyeonggi-do (KR); Taeil HONG, Gyeonggi-do (KR); Suyoung MOON, Gyeonggi-do (KR)

(21) Appl. No.: 18/814,597

(22) Filed: Aug. 26, 2024

(30) Foreign Application Priority Data
Nov. 6, 2023 (KR) 10-2023-0151984

(51) Int. Cl. B24B 37/22; B24B 37/24; B24D 18/00; H01L 21/3105

(52) U.S. Cl. CPC B24B 37/22; B24B 37/24; B24D 18/0027; H01L 21/31053

(57) ABSTRACT

The polishing pad according to an embodiment comprises a top-pad that is brought into contact with a wafer to perform polishing and a sub-pad that is located on one side of the top-pad, wherein the polishing rate at a distance of 95 mm from the center of the wafer in the polishing rate profile in a CMP process for a silicon oxide layer is greater than the polishing rate at a distance of 85 mm from the center of the wafer. As a result, the polishing rate and polishing flatness can be enhanced; in particular, the polishing rate profile characteristics of the polishing pad edge are excellent.

### CROSS-REFERENCE TO RELATED PATENT APPLICATION

This application claims priority under 35 U.S.C. § 119 to Korean Patent Application No. 10-2023-0151984, filed on Nov. 6, 2023, the disclosure of which is incorporated herein by reference in its entirety.

### TECHNICAL FIELD

Embodiments relate to a polishing pad for use in a chemical mechanical planarization (CMP) process of semiconductor devices. Specifically, they relate to a polishing pad and to a process for preparing the same.

### BACKGROUND ART

The chemical mechanical planarization (CMP) process in a process for preparing semiconductors refers to a step in which a semiconductor substrate such as a wafer is fixed to a head and in contact with the surface of a polishing pad mounted on a platen, and the platen and the head are relatively moved to planarize the irregularities on the surface of the semiconductor substrate.

In such a CMP process, the polishing pad is required to have stable physical properties because it greatly affects the surface processing quality of the semiconductor substrate. In particular, since the polishing rate of the CMP process may vary sensitively depending on the components contained in the polishing pad and their physical properties, it is necessary to optimize the components contained in the polishing pad and their physical properties.

Meanwhile, a polishing pad may be composed of a top-pad that is brought into contact with a wafer to perform polishing and a sub-pad that is located under the top-pad to support the top-pad. The sub-pad can be used to absorb and disperse an impact applied to the top-pad or to enhance characteristics such as polishing rate; however, there is a limit to enhancing characteristics such as polishing rate through such a sub-pad. Accordingly, research is continuing to further enhance characteristics such as the polishing rate of a polishing pad through a sub-pad.

### Prior Art Document

(Patent Document 1) Korean Laid-open Patent Publication No. 2018-0044771

### DISCLOSURE OF INVENTION

### Technical Problem

Accordingly, an embodiment aims to provide a polishing pad that comprises a specific sub-pad under a top-pad, whereby it can enhance the polishing rate and polishing flatness, without deteriorating the physical properties of the top-pad, and a process for preparing the same.

### Solution to Problem

The polishing pad according to an embodiment comprises a top-pad that is brought into contact with a wafer to perform polishing and a sub-pad that is located on one side of the top-pad, wherein the following Relationship 1 is satisfied.

RR₈₅<RR₉₅ [Relationship 1]

In Relationship 1, RR₈₅ is the polishing rate (Å/minute) at a distance of 85 mm from the center of the wafer in the polishing rate profile in a CMP process for a silicon oxide layer; and RR₉₅ is the polishing rate (Å/minute) at a distance of 95 mm from the center of the wafer in the polishing rate profile in a CMP process for a silicon oxide layer.

The process for preparing a polishing pad according to another embodiment comprises (1) preparing a top-pad using a top-pad composition comprising a urethane-based prepolymer, a foaming agent, and a curing agent; (2) preparing a sub-pad comprising a nonwoven fabric layer and a suede layer; and (3) combining the top-pad and the sub-pad to prepare a polishing pad, wherein the polishing pad satisfies the above Relationship 1.

The process for preparing a semiconductor device according to another embodiment comprises polishing the surface of a semiconductor substrate using the polishing pad.

### Advantageous Effects of Invention

The polishing pad according to an embodiment comprises a top-pad that is brought into contact with a wafer to perform polishing and a sub-pad that is located on one side of the top-pad, wherein the polishing rate at a distance of 95 mm from the center of the wafer in the polishing rate profile in a CMP process for a silicon oxide layer is greater than the polishing rate at a distance of 85 mm from the center of the wafer. As a result, the polishing rate and polishing flatness can be enhanced; in particular, the polishing rate profile characteristics of the polishing pad edge are excellent.

More specifically, the sub-pad has a dual structure comprising a nonwoven fabric layer and a suede layer, and physical properties such as hardness, compressibility, density, and the like of the sub-pad are adjusted. As a result, the slope between distances of 85 mm and 95 mm from the center of the wafer in the polishing rate profile in a CMP process satisfies a positive value, unlike the conventional polishing pads having a negative value. Accordingly, the polishing rate of a polishing pad can be enhanced; in particular, the polishing rate profile characteristics of the polishing pad edge are excellent, resulting in excellent polishing flatness.

In addition, since the polishing pad according to the embodiment can enhance the polishing rate and polishing flatness, without deteriorating the physical properties of the polishing pad and processability, it is possible to enhance CMP performance and yield when a semiconductor device is prepared using the same.

### BRIEF DESCRIPTION OF DRAWINGS

FIG. 1 is a scanning electron microscope (SEM) image of a cross-section of the sub-pad in Example 1.

FIG. 2 is a scanning electron microscope (SEM) image of a cross-section of the sub-pad in Comparative Example 1.

FIG. 3 is a scanning electron microscope (SEM) image of a cross-section of the sub-pad in Comparative Example 2.

FIG. 4 shows the polishing rate profile in a CMP process of the polishing pad of Example 1.

FIG. 5 shows the polishing rate profile in a CMP process of the polishing pad of Comparative Example 1.

FIG. 6 shows the polishing rate profile in a CMP process of the polishing pad of Comparative Example 2.

FIG. 7 shows the polishing rate profiles in a CMP process for the polishing pads of Example 1 and Comparative Examples 1 and 2.

FIG. 8 shows the slope between distances of 85 mm and 95 mm from the center of the wafer in the polishing rate profiles in a CMP process for the polishing pads of Example 1 and Comparative Examples 1 and 2.

FIG. 9 schematically illustrates a process for preparing a semiconductor device according to an embodiment.

### REFERENCE NUMERAL OF THE DRAWINGS

100: polishing pad, 200: platen, 300: conditioner, 400: polishing slurry,
510: polishing head, 520: carrier, 600: semiconductor substrate (wafer)

### BEST MODE FOR CARRYING OUT THE INVENTION

Hereinafter, the present invention will be described in detail with reference to embodiments. The embodiments are not limited to what has been disclosed below. The embodiments may be modified into various forms as long as the gist of the invention is not altered.

In this specification, terms referring to the respective components are used to distinguish them from each other and are not intended to limit the scope of the embodiment. In addition, in the present specification, a singular expression is interpreted to cover a plural number as well unless otherwise specified in the context.

Throughout the present specification, when a part is referred to as “comprising” an element, it is understood that other elements may be comprised, rather than other elements are excluded, unless specifically stated otherwise.

In the present specification, when one component is described to be formed on/under another component or connected or coupled to each other, it covers the cases where these components are directly or indirectly formed, connected, or coupled through another component. In addition, it should be understood that the criterion for the terms on and under of each component may vary depending on the direction in which the object is observed.

All numerical ranges related to the physical properties, dimensions, and the like of a component used herein are to be understood as being modified by the term “about,” unless otherwise indicated.

In the numerical range that limits the size, physical properties, and the like of components described in the present specification, when a numerical range limited with the upper limit only and a numerical range limited with the lower limit only are separately exemplified, it should be understood that a numerical range combining these upper and lower limits is also encompassed in the exemplary scope of the invention.

### Polishing Pad

The polishing pad according to an embodiment comprises a top-pad that is brought into contact with a wafer to perform polishing and a sub-pad that is located on one side of the top-pad, wherein the following Relationship 1 is satisfied.

$$R {R}_{85} < R {R}_{95} \qquad [ Relationship 1 ]$$

In Relationship 1, RR₈₅ is the polishing rate (Å/minute) at a distance of 85 mm from the center of the wafer in the polishing rate profile in a CMP process for a silicon oxide layer; and RR₉₅ is the polishing rate (Å/minute) at a distance of 95 mm from the center of the wafer in the polishing rate profile in a CMP process for a silicon oxide layer.

Specifically, a top-pad commonly prepared using a polyurethane material has viscoelasticity, which causes uneven pressure distribution in a CMP process, resulting in the deformation of the pad. In particular, due to the strong pressure applied to prevent the wafer from detaching, a rebounding phenomenon takes place, which may lead to a deterioration of the polishing rate profile characteristics at the edge in a CMP process.

In the polishing pad according to an embodiment, a sub-pad is provided on one side of the top-pad that is brought into contact with a wafer to perform polishing in order to enhance the polishing rate profile characteristics in a CMP process, more specifically, the polishing rate profile characteristics at the edge. The type and characteristics of the sub-pad are controlled, whereby it is possible to effectively control the viscoelastic properties of the top-pad. Accordingly, in the polishing pad according to an embodiment, the polishing rate at a distance of 95 mm from the center of the wafer in the polishing rate profile in a CMP process for a silicon oxide layer is greater than the polishing rate at a distance of 85 mm from the center of the wafer. As a result, the polishing rate and polishing flatness can be enhanced; in particular, the polishing rate profile characteristics of the polishing pad edge are excellent.

In the polishing pad according to an embodiment, the average slope between distances of 85 mm and 95 mm from the center of the wafer in the polishing rate profile in a CMP process for a silicon oxide layer has a positive value.

For example, in the polishing pad, the average slope between distances of 85 mm and 95 mm from the center of the wafer in the polishing rate profile in a CMP process for a silicon oxide layer may be 0.1 or more, 0.3 or more, 0.5 or more, 0.8 or more, 1.0 or more, 1.2 or more, 1.5 or more, 2 or more, 3 or more, 3.5 or more, 4 or more, 5.5 or more, 6 or more, 7 or more, 8 or more, 9.5 or more, 10.5 or more, 11 or more, 12 or more, 13.5 or more, or 15 or more, 1.5 to 15, 2 to 11.5, 3 to 10.5, 4.5 to 9, or 5 to 8.5. As the average slope between distances of 85 mm and 95 mm from the center of the wafer in the polishing rate profile in a CMP process for a silicon oxide layer satisfies the above range, the polishing rate and polishing flatness can be further enhanced.

In addition, the polishing pad may have a polishing rate difference (ΔRR) of 200 Å/minute or less according to the following Relationship 2.

$$Δ RR = R {R}_{95} - R {R}_{85} \qquad [ Relationship 2 ]$$

In Relationship 2, RR₈₅ is the polishing rate (Å/minute) at a distance of 85 mm from the center of the wafer in the polishing rate profile in a CMP process for a silicon oxide layer; and RR₉₅ is the polishing rate (Å/minute) at a distance of 95 mm from the center of the wafer in the polishing rate profile in a CMP process for a silicon oxide layer.

For example, the polishing rate difference (ΔRR) according to the above Relationship 2 may be 180 Å/minute or less, 150 Å/minute or less, 120 Å/minute or less, 100 Å/minute or less, 80 Å/minute or less, or 50 Å/minute or less. As the polishing pad according to an embodiment has a polishing rate difference according to the above Relationship 2 that satisfies the above range, it has excellent polishing uniformity.

In addition, RR₈₅ may be 1,950 Å/minute to 3,300 Å/minute, 2,000 Å/minute to 3,000 Å/minute, 2,100 Å/minute to 2,950 Å/minute, 2,250 Å/minute to 2,900 Å/minute, or 2,300 Å/minute to 2,650 Å/minute, and RR95 may be 2,000 Å/minute to 3,500 Å/minute, 2,150 Å/minute to 3,350 Å/minute, 2,200 Å/minute to 3,200 Å/minute, or 2,350 Å/minute to 3,000 Å/minute.

In addition, when the silicon oxide layer of a silicon wafer is polished with a ceria slurry using the polishing pad, the average polishing rate according to the following Mathematical Equation 1 may be 2,100 Å/minute to 3,500 Å/minute.

$$Average polishing rate ( \mathring{A} / minute ) = difference in thickness before and after polishing ( \mathring{A} ) / polishing time ( minute ) \qquad [ Mathematical Equation l ]$$

For example, when the silicon oxide layer of a silicon wafer is polished with a ceria slurry using the polishing pad, the average polishing rate (removal rate) may be 2,100 Å/minute to 3,300 Å/minute, 2,150 Å/minute to 3,100 Å/minute, 2,200 Å/minute to 2,950 Å/minute, or 2,250 Å/minute to 2,800 Å/minute.

Specifically, the polishing rate may be a polishing rate for a silicon wafer having a diameter of 300 mm on which silicon oxide has been deposited. In addition, the polishing rate may be measured under a polishing load of 4.0 psi while the polishing pad is rotated at a speed of 150 rpm, a calcined ceria slurry is supplied onto the polishing pad at a rate of 250 ml/minute, and the platen is rotated at a speed of 150 rpm for 60 seconds. The temperature condition when the polishing rate is measured is not particularly limited, but it may be, for example, a room temperature condition.

In addition, the polishing pad may have a within-wafer non-uniformity (WIWNU) of 10% or less for oxides. For example, the within-wafer non-uniformity of the polishing pad for oxides may be 9% or less, 7% or less, 5% or less, 4% or less, or 3% or less.

The within-wafer non-uniformity may be calculated by the following Mathematical Equation 2.

$$Within - wafer non - uniformity ( WIWNU ) ( \% ) = ( standard deviation of polished thickness ( \mathring{A} ) / average polished thickness ( \mathring{A} ) ) \times 100 ( \% ) \qquad [ Mathematical Equation 2 ]$$

### Sub-pad

The polishing pad according to an embodiment comprises a sub-pad. Specifically, the sub-pad is located on the lower side of the top-pad. More specifically, the sub-pad serves to support the top-pad, that is, the polishing layer and to absorb and disperse an impact applied to the polishing layer. Thus, it is possible to minimize damage and defects to the object to be polished during the polishing process using the polishing pad.

The sub-pad may have a structure in which a plurality of pores are formed, and the pores may have an open cell structure, but it is not limited thereto. In addition, the sub-pad may have a higher pore formation rate than that of the top-pad, and it may have lower hardness than that of the top-pad, making it softer.

According to an embodiment, the sub-pad may comprise a nonwoven fabric layer and a suede layer. Specifically, the sub-pad may comprise a suede layer on a nonwoven fabric layer, and the suede layer may be located on one side of the top-pad. More specifically, the polishing pad may have a structure in which the top-pad is stacked on the sub-pad, and it may have a structure in which the nonwoven fabric layer, the suede layer, and the top-pad are stacked.

The nonwoven fabric layer may be a nonwoven fabric layer impregnated with a resin. For example, the nonwoven fabric layer may be a fibrous nonwoven fabric layer comprising at least one fiber selected from the group consisting of a polyester fiber, a polyamide fiber, a polypropylene fiber, and a polyethylene fiber.

In addition, the resin impregnated in the nonwoven fabric layer may comprise at least one resin selected from the group consisting of a polyurethane resin, a polybutadiene resin, a styrene-butadiene copolymer resin, a styrene-butadiene-styrene copolymer resin, an acrylonitrile-butadiene copolymer resin, a styrene-ethylene-butadiene-styrene copolymer resin, a silicone rubber resin, a polyester-based elastomer resin, and a polyamide-based elastomer resin.

The suede layer may be combined with the nonwoven fabric layer to form a sub-pad. Specifically, the suede layer may be formed by casting a resin on the nonwoven fabric layer.

The resin that can be used in the preparation of the suede layer may comprise at least one resin selected from the group consisting of a polyurethane resin, a polybutadiene resin, a styrene-butadiene copolymer resin, a styrene-butadiene-styrene copolymer resin, an acrylonitrile-butadiene copolymer resin, a styrene-ethylene-butadiene-styrene copolymer resin, a silicone rubber resin, a polyester-based elastomer resin, and a polyamide-based elastomer resin.

The ratio of thicknesses of the nonwoven fabric layer and the suede layer may be 1:0.5 to 2. For example, the ratio of thicknesses of the nonwoven fabric layer and the suede layer may be 1:0.7 to 1.8, 1:0.9 to 1.5, 1:1 to 1.2, 1:0.7 to 0.9, or 1:1.5 to 1.8.

The sub-pad may have a thickness of 0.5 mm to 2.5 mm. For example, the total thickness of the sub-pad may be 0.6 mm or more, 0.7 mm or more, 0.85 mm or more, 0.95 mm or more, 1 mm or more, 1.1 mm or more, 1.3 mm or more, or 1.5 mm or more, 0.5 mm to 2.3 mm, 0.6 mm to 2.15 mm, 0.8 mm to 2 mm, 1 mm to 1.9 mm, 1.2 mm to 1.9 mm, or 1.3 mm to 1.85 mm.

In addition, the sub-pad may have a hardness of 60 Shore D to 90 Shore D. For example, the hardness of the sub-pad may be 62 Shore D to 85 Shore D, 65 Shore D to 85 Shore D, or 65 Shore D to 83 Shore D.

The sub-pad may have a compressibility of 5% to 15%. For example, the compressibility of the sub-pad may be 5.5% to 13%, 6% to 11.5%, 6.5% to 10%, or 7% to 9%.

Specifically, the sub-pad is cut to a length of 5 cm and a width of 5 cm, and a weight of 85 g is placed thereon for 30 seconds to measure the thickness (A) using a dial thickness gauge (Yasuda, 129-E) device. An additional weight of 800 g (a weight of 85 g and a weight of 800 g together) is placed thereon for 3 minutes to measure the thickness (B). The compressibility is then calculated according to the following Mathematical Equation 3.

$$Compressibility ( \% ) = [ ( A - B ) / A ] \times 100 \qquad [ Mathematical Equation 3 ]$$

In addition, the sub-pad may have a density of 0.25 g/cm³ to 0.7 g/cm³. For example, the density of the sub-pad may be 0.25 g/cm³ to 0.65 g/cm³, 0.3 g/cm³ to 0.65 g/cm³, or 0.3 g/cm³ to 0.6 g/cm³.

The sub-pad may have a compressive elasticity of 70% to 90%. For example, the compressive elasticity may be 72% to 88% or 75% to 85%.

Specifically, the compressive elasticity refers to the degree of recovery after compression. The sub-pad is cut to a length of 5 cm and a width of 5 cm, and a weight of 85 g is placed thereon for 30 seconds to measure the thickness (A) using a dial thickness gauge (Yasuda, 129-E) device. An additional weight of 800 g (a weight of 85 g and a weight of 800 g together) is placed thereon for 3 minutes, the weight of 800 g is removed, and it is then left to stand for 1 minute to measure the thickness (C). The compressive elasticity is calculated according to the following Mathematical Equation 4.

$$Compressibility elasticity ( \% ) = [ C / A ] \times 100 \qquad [ Mathematical Equation 4 ]$$

Although the sub-pad is thicker than a sub-pad composed of a single layer of nonwoven fabric or suede layer, its density is low and its hardness, compressibility, and compressive elasticity are controlled to desirable ranges. As a result, in the polishing rate profile in a CMP process, the polishing rate with respect to the distance from the center is evenly distributed, whereby polishing flatness can be enhanced. In particular, the polishing rate profile characteristics of the polishing pad edge can be enhanced.

In addition, an adhesive layer may be interposed between the top-pad and the sub-pad.

The adhesive layer may comprise a hot melt adhesive. The hot melt adhesive may be at least one selected from the group consisting of a polyurethane resin, a polyester resin, an ethylene-vinyl acetate resin, a polyamide resin, and a polyolefin resin. As a specific example, the hot melt adhesive may be at least one selected from the group consisting of a polyurethane resin and a polyester resin.

In addition, a double-sided adhesive tape may be laminated under the support layer. When it is applied to CMP equipment, it is attached to the platen for use once the release paper of the double-sided adhesive tape has been removed.

### Top-pad

The polishing pad according to an embodiment comprises a top-pad. Specifically, the top-pad refers to a component that is brought into contact with a wafer to perform polishing and comprises a polishing layer. More specifically, the top-pad comprises a polishing layer comprising a polyurethane resin.

The polishing layer comprises a urethane-based prepolymer, a foaming agent, and a curing agent. Specifically, the polyurethane resin may be formed from a composition that comprises a urethane-based prepolymer, a foaming agent, and a curing agent.

More specifically, the polishing layer comprises a polyurethane-based resin, which is a reaction product of a urethane-based prepolymer, a foaming agent, and a curing agent, i.e., a cured product of a composition in which the components are mixed. As a result, it comprises a porous polyurethane-based resin. In addition, the polishing layer may comprise a plurality of pores formed from the foaming agent.

The polishing layer may have a thickness of, for example, 0.8 mm or more, 1 mm or more, 1.2 mm or more, or 1.5 mm or more, and 5 mm or less, 3 mm or less, 2.5 mm or less, or 2 mm or less. As a specific example, the thickness of the polishing layer may be 0.8 mm to 5 mm or 1.5 mm to 3 mm.

The polishing layer may have a specific gravity of, for example, 0.6 g/cm³ or more, 0.7 g/cm³ or more, or 0.75 g/cm³ or more, and 0.9 g/cm³ or less, 0.85 g/cm³ or less, or 0.8 g/cm³ or less. As a specific example, the specific gravity of the polishing layer may be 0.6 g/cm³ to 0.9 g/cm³ or 0.7 g/cm³ to 0.9 g/cm³.

The polishing layer may have a hardness of, for example, 30 Shore D or more, 40 Shore D or more, or 50 Shore D or more, and 80 Shore D or less, 70 Shore D or less, 65 Shore D or less, or 60 Shore D or less. As a specific example, the hardness of the polishing layer may be 30 Shore D to 80 Shore D or 50 Shore D to 65 Shore D.

The polishing layer may have a tensile strength of, for example, 5 N/mm² or more, 10 N/mm² or more, or 15 N/mm² or more, and 30 N/mm² or less, 25 N/mm² or less, or 20 N/mm² or less. As a specific example, the tensile strength of the polishing layer may be 5 N/mm² to 30 N/mm² or 15 N/mm² to 25 N/mm².

The polishing layer may have an elongation of, for example, 50% or more, 70% or more, 90% or more, 106% or more, or 120% or more, and 300% or less, 250% or less, 200% or less, or 150% or less. As a specific example, the elongation of the polishing layer may be 50% to 300% or 90% to 130%. The elongation may be an elongation at break.

As a specific example, the polishing layer may have a hardness of 50 Shore D to 65 Shore D, a tensile strength of 15 N/mm² to 25 N/mm², and an elongation of 90% to 130%.

The pores are present as dispersed in the polishing layer.

The average diameter of the pores may be, for example, 10 μm to 60 μm, 10 μm to 50 μm, 20 μm to 50 μm, 20 μm to 40 μm, 10 μm to 30 μm, 20 μm to 25 μm, or 30 μm to 50 μm.

In addition, the total area of the pores may be 30% to 60%, 35% to 50%, or 35% to 43%, based on the total area of the polishing layer. In addition, the total volume of the pores may be 30 to 70%, or 40 to 60%, based on the total volume of the polishing layer.

The polishing layer may have grooves on its surface for mechanical polishing. The grooves may have a depth, a width, and a spacing as desired for mechanical polishing, which is not particularly limited.

The polishing pad according to an embodiment comprises a urethane-based prepolymer.

A prepolymer generally refers to a polymer having a relatively low molecular weight wherein the degree of polymerization is adjusted to an intermediate level for the sake of conveniently molding a product in the process of producing the same. A prepolymer may be molded by itself or after a reaction with another polymerizable compound. For example, a prepolymer may be prepared by reacting an isocyanate compound with a polyol.

The isocyanate compound used in the preparation of the urethane-based prepolymer may be one selected from the group consisting of an aromatic diisocyanate, an aliphatic diisocyanate, an alicyclic diisocyanate, or combinations thereof.

The isocyanate compound may comprise, for example, one selected from the group consisting of toluene 2,4-diisocyanate (2,4-TDI), toluene 2,6-diisocyanate (2,6-TDI), naphthalene 1,5-diisocyanate, para-phenylene diisocyanate, tolidine diisocyanate, 4,4′-diphenylmethane diisocyanate, hexamethylene diisocyanate, dicyclohexylmethane diisocyanate, isophorone diisocyanate, and combinations thereof.

The polyol is a compound comprising at least two or more hydroxyl groups (—OH) per molecule. For example, it may comprise one selected from the group consisting of a polyether polyol, a polyester polyol, a polycarbonate polyol, a polycaprolactone polyol, and combinations thereof.

The polyol may comprise, for example, one selected from the group consisting of polytetramethylene ether glycol, polypropylene ether glycol, ethylene glycol, 1,2-propylene glycol, 1,3-propylene glycol, 1,2-butanediol, 1,3-butanediol, 2-methyl-1,3-propanediol, 1,4-butanediol, neopentyl glycol, 1,5-pentanediol, 3-methyl-1,5-pentanediol, 1,6-hexanediol, diethylene glycol, dipropylene glycol, tripropylene glycol, and combinations thereof.

The polyol may have a weight average molecular weight (Mw) of 100 g/mole to 3,000 g/mole. For example, the weight average molecular weight of the polyol may be 100 g/mole to 3,000 g/mole, 100 g/mole to 2,000 g/mole, or 100 g/mole to 1,800 g/mole.

According to an embodiment, the polyol may comprise a low molecular weight polyol having a weight average molecular weight (Mw) of 100 g/mole to 300 g/mole and a high molecular weight polyol having a weight average molecular weight (Mw) of 300 g/mole to 1,800 g/mole.

In addition, the urethane-based prepolymer may have a weight average molecular weight (Mw) of 500 g/mole to 3,000 g/mole. For example, the weight average molecular weight of the urethane-based prepolymer may be 500 g/mole to 2,500 g/mole, 1,000 g/mole to 2,000 g/mole, or 1,000 g/mole to 1,500 g/mole.

According to an embodiment, the isocyanate compound for the preparation of the urethane-based prepolymer may comprise an aromatic diisocyanate compound, and the aromatic diisocyanate compound, for example, may comprise 2,4-toluene diisocyanate (2,4-TDI) and 2,6-toluene diisocyanate (2,6-TDI). The polyol compound for the preparation of the urethane-based prepolymer may comprise polytetramethylene ether glycol (PTMEG) and diethylene glycol (DEG).

According to an embodiment, the isocyanate compound for the preparation of the urethane-based prepolymer may comprise an aromatic diisocyanate compound and a cycloaliphatic diisocyanate compound. For example, the aromatic diisocyanate compound comprises 2,4-toluene diisocyanate (2,4-TDI) and 2,6-toluene diisocyanate (2,6-TDI), and the cycloaliphatic diisocyanate compound comprises dicyclohexylmethane diisocyanate (H12MDI). The polyol compound for the preparation of the urethane-based prepolymer may comprise polytetramethylene ether glycol (PTMEG) and diethylene glycol (DEG).

The urethane-based prepolymer may have an isocyanate end group content (NCO %) of 5% by weight or more, 8% by weight or more, or 10% by weight or more, and 13% by weight or less, 12% by weight or less, or 11% by weight or less. As a specific example, the urethane-based prepolymer may have an isocyanate end group content (NCO %) of 8% by weight to 11% by weight or 9% by weight to 10% by weight.

The isocyanate end group content (NCO %) of the urethane-based prepolymer may be designed by comprehensively adjusting the type and content of the isocyanate compound and the polyol compound for the preparation of the urethane-based prepolymer, the process conditions such as temperature, pressure, and time in the process for preparing the urethane-based prepolymer, and the type and content of the additives used in the preparation of the urethane-based prepolymer.

If the isocyanate end group content (NCO %) of the urethane-based prepolymer satisfies the above range, the reaction rate, reaction time, and final curing structure in the subsequent reaction between the urethane-based prepolymer and a curing agent can be adjusted in a way favorable to the polishing performance from the viewpoint of the use and purpose of a final polishing pad.

According to an embodiment, the urethane-based prepolymer may have an isocyanate end group content (NCO %) of 8% by weight to 11% by weight or 9% by weight to 10% by weight.

If the NCO % of the urethane-based prepolymer is less than the above range, the electrical properties based on the chemically hardened structure in the polishing pad may be achieved such that the desired polishing performance in terms of polishing rate and flatness are not achieved, and there may be a problem in that the lifespan of the polishing pad is reduced due to an excessive increase in the pad cut rate. On the other hand, if the NCO % exceeds the above range, surface defects such as scratches and chatter marks on a semiconductor substrate may increase.

The foaming agent is a component for forming a pore structure in the polishing layer. It may comprise one selected from the group consisting of a solid phase foaming agent, a gas phase foaming agent, a liquid phase foaming agent, and combinations thereof.

According to an embodiment, the foaming agent may be a non-chlorine-based foaming agent that does not contain a chlorine component. In particular, it may not contain, or minimize the use of, a chlorine-based foaming agent component commonly used in the preparation of polishing pads, such as vinylidene chloride (VDC). For example, the content of the non-chlorine-based foaming agent may be 50% by weight or more, 80% by weight or more, 90% by weight or more, 95% by weight or more, 97% by weight or more, 99% by weight or more, or 99.5% by weight or more, and 100% by weight or less or 99.5% by weight or less, as a specific example, 80% by weight to 100% by weight, 90% by weight to 100% by weight, or 80% by weight to 99.5% by weight, based on the total weight of the foaming agent. In addition, the content of the chlorine-based foaming agent may be 20% by weight or less, 10% by weight or less, 5% by weight or less, 1% by weight or less, 0.5% by weight or less, or 0.3% by weight or less, and 0% by weight or more, 0.1% by weight or more, 0.5% by weight or more, as a specific example, 0% by weight to 20% by weight, 0% by weight to 1% by weight, 0% by weight to 0.5% by weight, or 0.5% by weight to 20% by weight, based on the total weight of the foaming agent.

The foaming agent may be at least one selected from a solid phase foaming agent comprising particles having a hollow structure, a liquid phase foaming agent using a volatile liquid, and an inert gas.

As an example, the solid phase foaming agent may comprise particles having a hollow structure that have been expanded by heat and adjusted in size. Such a solid phase foaming agent has the advantage of controlling the size of pores to be uniform as it is employed in the raw material in an already expanded form and has a uniform particle size.

In addition, the solid phase foaming agent may comprise expandable particles. The expandable particles are particles having a characteristic that can be expanded by heat or pressure. Their size in the final polishing layer may be determined by heat or pressure applied in the process of preparing the polishing layer. The expandable particles are employed in the raw material in a particle state that has not been already expanded. Their final size is determined when expanded by heat or pressure applied during the process of preparing the polishing layer.

The solid phase foaming agent may have an average particle size of 5 μm to 100 μm, specifically, 5 μm to 50 μm or 20 μm to 50 μm. The average particle size of the solid phase foaming agent may refer to the average particle size of expanded particles themselves when the solid phase foaming agent is particles employed in the raw material in an expanded state as described below. It may refer to the average particle diameter of particles after they are expanded by heat or pressure in the preparation process when the solid phase foaming agent is particles employed in the raw material in an unexpanded state as described below.

The solid phase foaming agent in the form of expandable particles may comprise a shell of a resin; and an expansion-inducing component encapsulated inside the shell. These expandable particles may be formed into a hollow structure by the vaporization of the encapsulated expansion-inducing component by heat during the preparation process.

For example, the shell may comprise a thermoplastic resin. The thermoplastic resin may be at least one selected from the group consisting of an acrylonitrile-based copolymer, a methacrylonitrile-based copolymer, and an acrylic copolymer.

The thickness of the shell may be, for example, 0.1 μm or more, 0.5 μm or more, 1 μm or more, 2 μm or more, or 3 μm or more, and 15 μm or less, 12 μm or less, or 10 μm or less, as a specific example, 2 μm to 15 μm.

The expansion-inducing component may comprise one selected from the group consisting of a hydrocarbon compound, a tetraalkylsilane compound, and combinations thereof. Specifically, the hydrocarbon may comprise one selected from the group consisting of ethane, ethylene, propane, propene, n-butane, isobutane, n-butene, isobutene, n-pentane, isopentane, neopentane, n-hexane, heptane, petroleum ether, and combinations thereof. The tetraalkylsilane compound may comprise one selected from the group consisting of tetramethylsilane, trimethylethylsilane, trimethylisopropylsilane, trimethyl-n-propylsilane, and combinations thereof.

The solid phase foaming agent may comprise particles treated with an inorganic component. In an embodiment, the solid phase foaming agent may be one treated with silica (SiO₂) particles. The treatment of the solid phase foaming agent with an inorganic component can prevent aggregation between a plurality of particles. The solid phase foaming agent treated with an inorganic component may be different from the solid phase foaming agent that is not treated with an inorganic component in terms of the chemical, electrical, and/or physical properties of the surface of the foaming agent.

The commercial products of the solid phase foaming agent include Nouryon's 920DE20d70, 051DET40d25, and 051DET40d42 and Matsumoto's F-65DE, F-80DE, and FN-80SDE.

As a specific example, the foaming agent used in the polishing pad according to an embodiment comprises a solid phase foaming agent. The solid phase foaming agent may comprise at least one selected from the group consisting of an acrylonitrile-based copolymer, a methylmethacrylate-based copolymer, a methacrylonitrile-based copolymer, and an acrylic-based copolymer.

The content of the solid phase foaming agent may be 0.1 part by weight or more, 0.5 part by weight or more, or 1 part by weight or more, and 5 parts by weight or less, 3 parts by weight or less, or 2 parts by weight or less, relative to 100 parts by weight of the urethane-based prepolymer. As a specific example, the content of the solid phase foaming agent may be 0.1 part by weight to 5 parts by weight or 0.5 part by weight to 2 parts by weight, relative to 100 parts by weight of the urethane-based prepolymer.

The type and content of the solid phase foaming agent may be designed according to the desired pore structure and physical properties of the polishing layer.

Meanwhile, the liquid phase foaming agent may be introduced during the mixing and reaction of the prepolymer and the curing agent to form pores. It does not participate in the reaction between the prepolymer and the curing agent. In addition, the liquid phase foaming agent is physically vaporized by heat generated during the mixing and reaction of the prepolymer and the curing agents to form pores.

The volatile liquid phase foaming agent may be liquid at 25° C. while it does not react with an isocyanate group, an amide group, and an alcohol group. Specifically, the volatile liquid phase foaming agent may be selected from the group consisting of cyclopentane, n-pentane, cyclohexane, n-butyl acetate, bis(nonafluorobutyl)(trifluoromethyl)amine; and perfluoro compounds such as perfluorotributylamine, perfluoro-N-methylmorpholine, perfluorotripentylamine, and perfluorohexane. Commercially available products of the perfluoro compound include FC-40 (3M), FC-43 (3M), FC-70 (3M), FC-72 (3M), FC-770 (3M), FC-3283 (3M), and FC-3284 (3M).

In addition, the foaming agent may comprise a gas phase foaming agent. For example, the foaming agent may comprise a solid phase foaming agent and a gas phase foaming agent.

The gas phase foaming agent may comprise an inert gas. The gas phase foaming agent is fed while the urethane-based prepolymer and the curing agent are reacted in order to be used as a component to form pores.

The kind of the inert gas is not particularly limited as long as it is a gas that does not participate in the reaction between the urethane-based prepolymer and the curing agent. For example, the inert gas may comprise one selected from the group consisting of nitrogen gas (N₂), carbon dioxide gas (CO₂), argon gas (Ar), helium gas (He), and combinations thereof.

The type and content of the gas phase foaming agent may be designed according to the desired pore structure and physical properties of the polishing layer.

The inert gas may be fed in a volume of 10% to 30% based on the total volume of the composition. Specifically, the inert gas may be fed in a volume of 15% to 30% based on the total volume of the composition. Specifically, the gas phase foaming agent may be fed through a predetermined feeding line while the urethane-based prepolymer, the solid phase foaming agent, and the curing agent are mixed. For example, the feeding rate of the gas phase foaming agent is about 0.8 L/minute to about 2.0 L/minute, about 0.8 L minute to about 1.8 L/minute, about 0.8 L/minute to about 1.7 L/minute, about 1.0 L/minute to about 2.0 L/minute, about 1.0 L/minute to about 1.8 L/minute, or about 1.0 L/minute to about 1.7 L/minute.

The curing agent is a compound for chemically reacting with the urethane-based prepolymer to form a final cured structure in the polishing layer. For example, it may comprise an amine compound or an alcohol compound. Specifically, the curing agent may comprise one selected from the group consisting of an aromatic amine, an aliphatic amine, an aromatic alcohol, an aliphatic alcohol, and combinations thereof.

According to an embodiment, the curing agent may comprise a non-chlorine-based curing agent that does not contain a chlorine component. For example, the content of the non-chlorine-based curing agent may be 50% by weight or more, 80% by weight or more, 90% by weight or more, 95% by weight or more, 97% by weight or more, 99% by weight or more, or 99.5% by weight or more, and 100% by weight or less or 99.5% by weight or less, as a specific example, 80% by weight to 100% by weight, 90% by weight to 100% by weight, or 80% by weight to 99.5% by weight, based on the total weight of the curing agent. In addition, the content of the chlorine-based curing agent may be 20% by weight or less, 10% by weight or less, 5% by weight or less, 1% by weight or less, 0.5% by weight or less, or 0.3% by weight or less, and 0% by weight or more, 0.1% by weight or more, 0.5% by weight or more, as a specific example, 0% by weight to 20% by weight, 0% by weight to 1% by weight, 0% by weight to 0.5% by weight, or 0.5% by weight to 20% by weight, based on the total weight of the curing agent.

The curing agent may be at least one selected from a solid phase curing agent and a liquid phase curing agent.

The solid phase curing agent may contain an active hydrogen group. The solid phase curing agent may contain an amine group (—NH₂) as an active hydrogen group.

In addition, the solid phase curing agent may be an ester compound containing two or more benzene rings. Specifically, the solid phase curing agent may comprise two or more of the ester groups in the molecule.

The solid phase curing agent may have a weight average molecular weight of, for example, 150 g/mole to 400 g/mole, 150 g/mole to 350 g/mole, 200 g/mole to 350 g/mole, 250 g/mole to 350 g/mole, or 300 g/mole to 350 g/mole. In addition, the solid phase curing agent may have a melting point (m.p.) of 100° C. to 150° C., 100° C. to 140° C., or 110° C. to 130° C.

In an embodiment, the solid phase curing agent comprises at least one selected from the group consisting of 1,3-propanediol bis(4-aminobenzoate) (PDPAB), 4-(4-aminobenzoyl)oxyphenyl 4-aminobenzoate, 4-(4-aminobenzoyl)oxybutyl 4-aminobenzoate, 4-[4-(4-aminobenzoyl)oxy-3-methylbutoxy]butyl 4-aminobenzoate, and methylene bis-methylanthranilate (MBNA).

The liquid phase curing agent may contain an active hydrogen group. The liquid phase curing agent may contain at least one selected from the group consisting of an amine group (—NH₂), a hydroxyl group (—OH), a carboxylic acid group (—COOH), an epoxy group, and a combination thereof as an active hydrogen group. Specifically, it may contain an amine group (—NH₂).

In addition, the liquid phase curing agent may contain sulfur in the molecule. Specifically, it may contain two or more sulfur elements in the molecule.

The liquid phase curing agent may have a weight average molecular weight of 50 to 300, for example, 100 to 250, for example, 150 to 250, for example, 200 to 250.

In addition, the liquid phase curing agent may be liquid at room temperature. Alternatively, the liquid phase curing agent may have a boiling point (b.p.) of 160° C. to 240° C., specifically 170° C. to 240° C., more specifically 170° C. to 220° C.

Examples of the liquid phase curing agent include at least one selected from the group consisting of 3,5-dimethylthio-2,6-diaminotoluene (DMTDA), 2,6-bis(methylthio)-4-methyl-1,3-benzenediamine, and N,N′-bis(sec-butylamino)diphenylmethane.

In addition, the curing agent may further comprise other curing agents in addition to the liquid phase curing agent and the solid phase curing agent. The additional curing agent may be, for example, at least one of an amine compound and an alcohol compound. Specifically, the additional curing agent may comprise at least one compound selected from the group consisting of an aromatic amine, an aliphatic amine, an aromatic alcohol, and an aliphatic alcohol.

For example, the additional curing agent may be at least one selected from the group consisting of diaminodiphenylmethane, diaminodiphenyl sulphone, m-xylylene diamine, isophoronediamine, ethylenediamine, diethylenetriamine, triethylenetetramine, polypropylenediamine, polypropylenetriamine, ethylene glycol, diethylene glycol, dipropylene glycol, butanediol, hexanediol, glycerin, and trimethylolpropane.

As a specific example, the curing agent may comprise at least one selected from the group consisting of 4,4′-methylenebis(2-chloroaniline) (MOCA), diethyltoluenediamine (DETDA), 3,5-dimethylthio-2,6-diaminotoluene (DMTDA), 1,3-propanediol bis(4-aminobenzoate) (PDPAB), N,N′-bis(sec-butylamino)diphenylmethane, 2,6-bis(methylthio)-4-methyl-1,3-benzenediamine, 4-(4-aminobenzoyl)oxyphenyl 4-aminobenzoate, 4-(4-aminobenzoyl)oxybutyl 4-aminobenzoate, 4-[4-(4-aminobenzoyl)oxy-3-methylbutoxy]butyl 4-aminobenzoate, and methylene bis-methylanthranilate (MBNA).

The content of the curing agent may be 5 parts by weight or more, 10 parts by weight or more, 15 parts by weight or more, or 20 parts by weight or more, and 50 parts by weight or less, 45 parts by weight or less, 40 parts by weight or less, 35 parts by weight or less, 30 parts by weight or less, or 25 parts by weight or less, relative to 100 parts by weight of the urethane-based prepolymer. The content of the curing agent may be 10 parts by weight to 40 parts by weight, more specifically, 15 parts by weight to 35 parts by weight or 15 parts by weight to 25 parts by weight, relative to 100 parts by weight of the urethane-based prepolymer.

In addition, the equivalence ratio of the urethane-based prepolymer and the curing agent may be 1:0.5 to 2. For example, the equivalence ratio of the urethane-based prepolymer and the curing agent may be 1:0.5 to 1.5, 1:0.5 to 1.0, or 1:0.6 to 1.2.

The composition for preparing a polishing layer may further comprise other additives such as a surfactant and a reaction rate controlling agent. The names such as “surfactant” and “reaction rate controlling agent” are arbitrary names based on the main role of the substances. The respective substances do not necessarily perform only a function limited to the role defined by the names.

The surfactant is not particularly limited as long as it acts to prevent pores from coalescing and overlapping with each other. For example, the surfactant may comprise a silicone-based surfactant.

The surfactant may be employed in an amount of 0.2 part by weight to 2 parts by weight relative to 100 parts by weight of the urethane-based prepolymer. Specifically, the surfactant may be employed in an amount of 0.2 part by weight to 1.9 parts by weight, 0.2 part by weight to 1.8 parts by weight, 0.2 part by weight to 1.7 parts by weight, 0.2 part by weight to 1.6 parts by weight, 0.2 part by weight to 1.5 parts, or 0.5 part by weight to 1.5 parts by weight, relative to 100 parts by weight of the urethane-based prepolymer. If the amount of the surfactant is within the above range, pores derived from the gas phase foaming agent can be stably formed and maintained in the mold.

The reaction rate controlling agent serves to promote or retard the reaction. A reaction promoter, a reaction retarder, or both may be used depending on the purpose. The reaction rate controlling agent may comprise a reaction promoter. For example, the reaction rate controlling agent may be at least one reaction promoter selected from the group consisting of a tertiary amine-based compound and an organometallic compound.

Specifically, the reaction rate controlling agent may comprise at least one selected from the group consisting of triethylenediamine, dimethylethanolamine, tetramethylbutanediamine, 2-methyl-triethylenediamine, dimethylcyclohexylamine, triethylamine, triisopropanolamine, 1,4-diazabicyclo(2,2,2)octane, bis(2-methylaminoethyl) ether, trimethylaminoethylethanolamine, N,N,N,N,N″-pentamethyldiethylenetriamine, dimethylaminoethylamine, dimethylaminopropylamine, benzyldimethylamine, N-ethylmorpholine, N,N-dimethylaminoethylmorpholine, N,N-dimethylcyclohexylamine, 2-methyl-2-azanorbornane, dibutyltin dilaurate, stannous octoate, dibutyltin diacetate, dioctyltin diacetate, dibutyltin maleate, dibutyltin di-2-ethylhexanoate, and dibutyltin dimercaptide. Specifically, the reaction rate controlling agent may comprise at least one selected from the group consisting of benzyldimethylamine, N,N-dimethylcyclohexylamine, and triethylamine.

The reaction rate controlling agent may be employed in an amount of 0.05 part by weight to 2 parts by weight relative to 100 parts by weight of the urethane-based prepolymer. Specifically, the reaction rate controlling agent may be employed in an amount of 0.05 part by weight to 1.8 parts by weight, 0.05 part by weight to 1.7 parts by weight, 0.05 part by weight to 1.6 parts by weight, 0.1 part by weight to 1.5 parts by weight, 0.1 part by weight to 0.3 part by weight, 0.2 part by weight to 1.8 parts by weight, 0.2 part by weight to 1.7 parts by weight, 0.2 part by weight to 1.6 parts by weight, 0.2 part by weight to 1.5 parts by weight, or 0.5 part by weight to 1 part by weight, relative to 100 parts by weight of the urethane-based prepolymer. If the reaction rate controlling agent is used in the above content range, the curing reaction rate of the prepolymer composition may be appropriately controlled to form a polishing layer having pores of a desired size and hardness.

### Process for Preparing a Polishing Pad

The process for preparing a polishing pad according to another embodiment comprises (1) preparing a top-pad using a top-pad composition comprising a urethane-based prepolymer, a foaming agent, and a curing agent; (2) preparing a sub-pad comprising a nonwoven fabric layer and a suede layer; and (3) combining the top-pad and the sub-pad to prepare a polishing pad, wherein the polishing pad satisfies the above Relationship 1.

### (1) Step of Preparing a Top-pad Using a Top-pad Composition Comprising a Urethane-based Prepolymer, a Foaming Agent, and a Curing Agent

The process for preparing a polishing pad according to another embodiment comprises (1) preparing a top-pad using a top-pad composition comprising a urethane-based prepolymer, a foaming agent, and a curing agent.

The specific types and contents of the urethane-based prepolymer, curing agent, and foaming agent are as exemplified above.

As a specific example, the foaming agent comprises a solid phase foaming agent, the solid phase foaming agent comprises at least one selected from the group consisting of an acrylonitrile-based copolymer, a methyl methacrylate-based copolymer, a methacrylonitrile-based copolymer, and an acrylic-based copolymer, and the curing agent comprises at least one selected from the group consisting of diethyltoluenediamine (DETDA), 3,5-dimethylthio-2,6-diaminotoluene (DMTDA), 1,3-propanediol bis(4-aminobenzoate) (PDPAB), N,N′-bis(sec-butylamino)diphenylmethane, 2,6-bis(methylthio)-4-methyl-1,3-benzenediamine, 4-(4-aminobenzoyl)oxyphenyl 4-aminobenzoate, 4-(4-aminobenzoyl)oxybutyl 4-aminobenzoate, 4-[4-(4-aminobenzoyl)oxy-3-methylbutoxy]butyl 4-aminobenzoate, and methylene bis-methylanthranilate (MBNA).

The composition for a top-pad may be prepared by sequentially or simultaneously mixing a urethane-based prepolymer, a foaming agent, and a curing agent.

As an example, the step of preparing the composition for a top-pad may be carried out by mixing a urethane-based prepolymer with a curing agent, followed by further mixing with a foaming agent, or by mixing the urethane-based prepolymer with the foaming agent, followed by further mixing with the curing agent.

As another example, a urethane-based prepolymer, a curing agent, and a foaming agent may be put into the mixing process substantially at the same time. If a foaming agent, a surfactant, and an inert gas are further added, they may be put into the mixing process substantially at the same time.

As another example, a urethane-based prepolymer, a foaming agent, and a surfactant may be mixed in advance, and a curing agent, or a curing agent with an inert gas, may be subsequently added.

The mixing initiates the reaction of the urethane-based prepolymer and the curing agent and uniformly disperses the foaming agent and the inert gas in the raw materials. In such an event, a reaction rate controlling agent may intervene in the reaction between the urethane-based prepolymer and the curing agent from the beginning of the reaction, to thereby control the reaction rate. Specifically, the mixing may be carried out at a speed of 1,000 rpm to 10,000 rpm or 4,000 rpm to 7,000 rpm. Within the above speed range, it may be more advantageous for the inert gas and the foaming agent to be uniformly dispersed in the raw materials.

In addition, the step of preparing the composition for a top-pad may be carried out under the condition of 50° C. to 150° C. If necessary, it may be carried out under vacuum defoaming conditions.

If the foaming agent comprises a solid phase foaming agent, the step of preparing the composition for a top-pad may comprise mixing the urethane-based prepolymer and the solid phase foaming agent to prepare a first preliminary composition; and mixing the first preliminary composition and the curing agent to prepare a second preliminary composition.

The first preliminary composition may have a viscosity at about 80° C. of about 1,000 cps to about 2,000 cps, about 1,000 cps to about 1,800 cps, about 1,000 cps to about 1,600 cps, or about 1,000 cps to about 1,500 cps.

If the foaming agent comprises a gas phase foaming agent, the step of preparing the composition for a top-pad may comprise preparing a third preliminary composition comprising the urethane-based prepolymer and the curing agent; and feeding the gas phase foaming agent to the third preliminary composition to prepare a fourth preliminary composition. In an embodiment, the third preliminary composition may further comprise a solid phase foaming agent.

In an embodiment, the step of preparing a polishing layer comprises preparing a mold preheated to a first temperature; and injecting the composition for a top-pad into the preheated mold and curing it; and post-curing the cured composition for a top-pad under a second temperature condition higher than the preheating temperature.

According to an embodiment, the temperature difference between the first temperature and the second temperature may be about 10° C. to about 40° C., for example, about 10° C. to about 35° C. or about 15° C. to about 35° C. In an embodiment, the first temperature may be about 60° C. to about 100° C., about 65° C. to about 95° C., or about 70° C. to about 90° C. In an embodiment, the second temperature may be about 100° C. to about 130° C., for example, about 100° C. to about 125° C. or about 100° C. to about 120° C.

The step of curing the composition for a top-pad at the first temperature may be carried out for about 5 minutes to about 60 minutes, about 5 minutes to about 40 minutes, about 5 minutes to about 30 minutes, or about 5 minutes to about 25 minutes.

The step of post-curing the composition for a top-pad cured at the first temperature at the second temperature may be carried out for about 5 hours to about 30 hours, about 5 hours to about 25 hours, about 10 hours to about 30 hours, about 10 hours to about 25 hours, about 12 hours to about 24 hours, or about 15 hours to about 24 hours.

Thereafter, the step of injecting the composition for a top-pad into a mold and curing it may be carried out under the temperature condition of 60° C. to 120° C. and the pressure condition of 50 kg/m² to 200 kg/m².

In addition, the process for preparing a top-pad may further comprise the steps of cutting the surface of a top-pad thus obtained, machining grooves on the surface thereof, and the like. These steps may be carried out in a conventional process for preparing a top-pad.

As a specific example, the process for preparing a top-pad may further comprise machining at least one side of the polishing layer. The step of machining at least one side of the polishing layer may comprise forming grooves on at least one side of the polishing layer; line turning at least one side of the polishing layer; and roughening at least one side of the polishing layer.

The grooves may comprise at least one of concentric circular grooves spaced apart from the center of the polishing layer at a certain interval; and radial grooves continuously connected from the center of the polishing layer to the edge of the polishing layer. The line turning may be carried out by cutting the polishing layer to a certain thickness using a cutting tool. The roughening may be carried out by machining the surface of the polishing layer with a sanding roller.

### (2) Step of Preparing a Sub-pad Comprising a Nonwoven Fabric Layer and a Suede Layer

The process for preparing a polishing pad according to another embodiment comprises (2) preparing a sub-pad comprising a nonwoven fabric layer and a suede layer.

Specifically, a nonwoven fabric layer is first prepared, and a suede layer is then formed on the nonwoven fabric layer, whereby a sub-pad composed of a dual structure of the nonwoven fabric layer and the suede layer may be prepared.

More specifically, step (2) comprises impregnating a nonwoven fabric with a resin to prepare a nonwoven fabric layer; and casting a resin on one side of the nonwoven fabric layer to form a suede layer.

First, a nonwoven fabric is impregnated with a resin to prepare a nonwoven fabric layer.

The nonwoven fabric may be a fibrous nonwoven fabric comprising at least one fiber selected from the group consisting of a polyester fiber, a polyamide fiber, a polypropylene fiber, and a polyethylene fiber. In addition, the impregnated resin may comprise at least one resin selected from the group consisting of a polyurethane resin, a polybutadiene resin, a styrene-butadiene copolymer resin, a styrene-butadiene-styrene copolymer resin, an acrylonitrile-butadiene copolymer resin, a styrene-ethylene-butadiene-styrene copolymer resin, a silicone rubber resin, a polyester-based elastomer resin, and a polyamide-based elastomer resin.

Specifically, the nonwoven fabric is impregnated with the resin to prepare the nonwoven fabric layer. As a specific example, the nonwoven fabric layer may be formed by impregnating a polyester fiber with a polyurethane resin and then drying the same. The drying step may be carried out at 120° C. to 150° C. or 125° C. to 145° C. for 5 minutes to 60 minutes or 5 minutes to 30 minutes.

The suede layer may be formed by casting a resin on the nonwoven fabric layer. For example, the suede layer may be formed by casting at least one resin selected from the group consisting of a polyurethane resin, a polybutadiene resin, a styrene-butadiene copolymer resin, a styrene-butadiene-styrene copolymer resin, an acrylonitrile-butadiene copolymer resin, a styrene-ethylene-butadiene-styrene copolymer resin, a silicone rubber resin, a polyester-based elastomer resin, and a polyamide-based elastomer resin, on the nonwoven fabric layer prepared above. As a specific example, the suede layer may be formed by casting a polyurethane resin on the nonwoven fabric layer and then drying the same. The drying step may be carried out at 120° C. to 150° C. or 125° C. to 145° C. for 5 minutes to 60 minutes or 5 minutes to 30 minutes.

In addition, once the suede layer has been formed on the nonwoven fabric layer, both sides of the sub-pad, that is, the outer surfaces of the nonwoven fabric layer and the suede layer, may be subjected to sanding treatment. As a specific example, it may be carried out by processing the outer surfaces of the nonwoven fabric layer and the suede layer with a sanding roller.

### (3) Step of Combining the Top-pad and the Sub-pad to Prepare a Polishing Pad

The process for preparing a polishing pad according to another embodiment comprises (3) combining the top-pad and the sub-pad to prepare a polishing pad.

For example, the combination of the top-pad and the sub-pad may be carried out using an adhesive layer. As a specific example, the sub-pad is placed under the top-pad, and the top-pad and the sub-pad are combined using a hot melt adhesive.

The hot melt adhesive may be at least one selected from the group consisting of a polyurethane resin, a polyester resin, an ethylene-vinyl acetate resin, a polyamide resin, and a polyolefin resin. As a specific example, the hot melt adhesive may be at least one selected from the group consisting of a polyurethane resin and a polyester resin.

In addition, a double-sided adhesive tape may be laminated under the support layer. When it is applied to CMP equipment, it is attached to the platen for use once the release paper of the double-sided adhesive tape has been removed.

### Process for Preparing a Semiconductor Device

The process for preparing a semiconductor device according to another embodiment comprises polishing the surface of a semiconductor substrate using the polishing pad.

Specifically, the process for preparing a semiconductor device may comprise providing the polishing pad according to an embodiment; and relatively rotating the polishing surface of the polishing layer and the surface of a semiconductor substrate while they are in contact with each other to polish the surface of the semiconductor substrate.

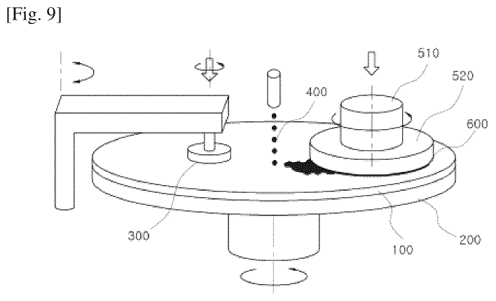

FIG. 9 illustrates a process for preparing a semiconductor device using a polishing pad according to an embodiment. Referring to FIG. 9, once the polishing pad (100) according to an embodiment has been attached to a platen (200), a semiconductor substrate (600) as an object to be polished is disposed on the polishing pad (100). In such an event, the surface of the semiconductor substrate (600) to be polished is in direct contact with the polishing surface of the polishing pad (100). A polishing slurry (400) may be sprayed through a nozzle onto the polishing pad for polishing. The flow rate of the polishing slurry (400) supplied through the nozzle may be selected according to the purpose within a range of about 10 cm³/minute to about 1,000 cm³/minute. For example, it may be about 50 cm³/minute to about 500 cm³/minute, but it is not limited thereto.

Thereafter, the semiconductor substrate (600) and the polishing pad (100) rotate relatively to each other, so that the surface of the semiconductor substrate (600) is polished. In such an event, the rotation direction of the semiconductor substrate (600) and the rotation direction of the polishing pad (100) may be the same direction or opposite directions. The rotation speeds of the semiconductor substrate (600) and the polishing pad (100) may each be selected according to the purpose within a range of about 10 rpm to about 500 rpm. For example, it may be about 30 rpm to about 200 rpm, but it is not limited thereto.

The semiconductor substrate (600) mounted on the polishing head (510) is pressed against the polishing surface of the polishing pad (100) at a predetermined load to be in contact therewith, and the surface thereof may then be polished. The load applied to the polishing surface of the polishing pad (100) through the surface of the semiconductor substrate (600) by the polishing head (510) may be selected according to the purpose within a range of about 1 gf/cm² to about 1,000 gf/cm². For example, it may be about 10 gf/cm² to about 800 gf/cm², but it is not limited thereto.

In an embodiment, the semiconductor substrate (600) as an object to be polished may comprise an oxide layer, a tungsten layer, or a composite layer thereof. Specifically, the semiconductor substrate (600) may comprise an oxide layer, a tungsten layer, or a composite layer of an oxide layer and a tungsten layer. The composite layer of an oxide layer and a tungsten layer may be a multilayer film in which the tungsten layer is laminated on one side of the oxide layer or may be a single-layer film in which an oxide region and a tungsten region are mixed in a single layer. As the object to be polished has such a film substance, and, at the same time, the polishing pad has characteristics according to the embodiment, a semiconductor device fabricated according to the process for preparing a semiconductor device may have minimum defects.

In an embodiment, the process for preparing a semiconductor device may further comprise, in the step of polishing the object to be polished, supplying any one of a slurry for polishing an oxide layer and a slurry for polishing a tungsten layer; or sequentially supplying the slurry for polishing an oxide layer and the slurry for polishing a tungsten layer to the polishing surface.

For example, if the semiconductor substrate as an object to be polished comprises an oxide layer, the process for preparing a semiconductor device may comprise supplying a slurry for polishing an oxide layer. If the semiconductor substrate comprises a tungsten layer, the process for preparing a semiconductor device may comprise supplying a slurry for polishing a tungsten layer. If the semiconductor substrate comprises a composite layer of an oxide layer and a tungsten layer, the process for preparing a semiconductor device may comprise sequentially supplying a slurry for polishing an oxide layer and a slurry for polishing a tungsten layer to the polishing surface. Here, depending on the process, the slurry for polishing an oxide layer may be supplied first and then the slurry for polishing a tungsten layer may be supplied later, or the slurry for polishing a tungsten layer may be supplied first and then the slurry for polishing an oxide layer may be supplied later.

In an embodiment, in order to maintain the polishing surface of the polishing pad (100) in a state suitable for polishing, the process for preparing a semiconductor device may further comprise processing the polishing surface of the polishing pad (100) with a conditioner (470) simultaneously with polishing the semiconductor substrate (600).

As the polishing pad according to an embodiment has a content of chlorine in the polishing layer adjusted to a certain range, it is possible to reduce the size of debris while maintaining excellent physical properties and performance of the polishing pad, thereby minimizing the occurrence of defects and scratches during a CMP process. Thus, it is possible to efficiently prepare a semiconductor device with high quality using the polishing pad.

### Mode for the Invention

Hereinafter, the present invention is explained in detail by Examples. The following Examples are intended to further illustrate the present invention, and the scope of the Examples is not limited thereto.

### PREPARATION OF A POLISHING PAD

### Example 1

### (1) Preparation of a Top-pad

A four-necked flask was charged with toluene diisocyanate (TDI), dicyclohexylmethane diisocyanate (H12MDI), polytetramethylene ether glycol (PTMEG), and diethylene glycol (DEG), followed by reaction thereof at 80° C. for 3 hours, thereby preparing a urethane-based prepolymer having an isocyanate end group content (NCO %) of 8% by weight to 12% by weight.

A casting machine equipped with tanks and feeding lines for the raw materials such as the urethane-based prepolymer, a curing agent, and an inert gas was provided. Specifically, the urethane-based prepolymer prepared in step (1), a curing agent (4,4′-methylenebis(2-chloroaniline), MOCA), a solid phase foaming agent (average particle size: 20 μm), an inert gas (N₂), and a silicone-based surfactant (manufacturer: Evonik) were each charged to the tanks. Here, the solid phase foaming agent was fed at 1.5 parts by weight relative to 100 parts by weight of the urethane-based prepolymer, and the urethane-based prepolymer and the curing agent were fed at an equivalence ratio of 1:1 and a total amount of 10 kg/minute.

Thereafter, the raw materials were stirred while they were fed to the mixing head at constant rates through the respective feeding lines (mixing head rotation speed: approximately 5,000 rpm). A mold (1,000 mm×1,000 mm×3 mm) was prepared and preheated at a temperature of 80° C. The stirred mixture was injected into the mold and reacted to obtain a molded article in the form of a solid cake. Thereafter, the top and bottom of the molded article were each ground to obtain a polishing layer for a top-pad. Here, the top-pad had a thickness of 2 mm, a hardness of 58.8 Shore D, a specific gravity of 0.79 g/cc, and an elongation of 111%.

### (2) Preparation of a Sub-pad

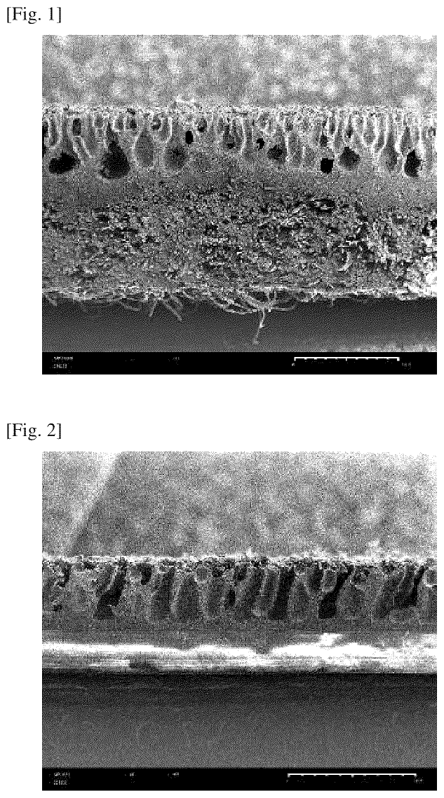

A polyester-based fiber nonwoven fabric was impregnated with a polyurethane resin and dried at 140° C. for 10 minutes to prepare a nonwoven fabric layer with a thickness of about 0.7 mm. A polyurethane resin was cast on the nonwoven fabric layer, which was dried at 140° C. for 10 minutes to form a suede layer with a thickness of about 0.8 mm, thereby preparing a sub-pad composed of a dual structure of the nonwoven fabric layer and the suede layer (total thickness: 1.53 mm). Then, both sides of the sub-pad were subjected to sanding treatment. FIG. 1 is a scanning electron microscope (SEM) image of a cross-section of the sub-pad in Example 1.

### (3) Preparation of a Polishing Pad

The top-pad prepared in step (1) was subjected to surface milling and groove forming steps. Then, the sub-pad prepared in step (2) was placed under the top-pad, and the top-pad and the sub-pad were combined using a hot melt adhesive to prepare a polishing pad (total thickness: 3.55 mm). In such an event, the suede layer of the sub-pad was combined such that it was brought into contact with the top-pad. In addition, a double-sided adhesive tape (model name: 442JS, manufacturer: 3M) was laminated under the sub-pad so that it could be attached to the platen of CMP equipment.

### Comparative Example 1

### (1) Preparation of a Top-pad

A top-pad was prepared in the same manner as in Example 1.

### (2) Preparation of a Sub-pad

A polyurethane resin was cast on a polyethylene terephthalate (PET) film, which was dried at 140° C. for 10 minutes to form a suede layer with a thickness of about 0.63 mm, thereby preparing a sub-pad having a single structure of the suede layer. Then, the surface of the suede layer was subjected to sanding treatment. FIG. 2 is a scanning electron microscope (SEM) image of a cross-section of the sub-pad in Comparative Example 1.

### (3) Preparation of a Polishing Pad

A polishing pad (total thickness: 2.65 mm) was prepared in the same manner as in Example 1.

### Comparative Example 2

### (1) Preparation of a Top-pad

A top-pad was prepared in the same manner as in Example 1.

### (2) Preparation of a Sub-pad

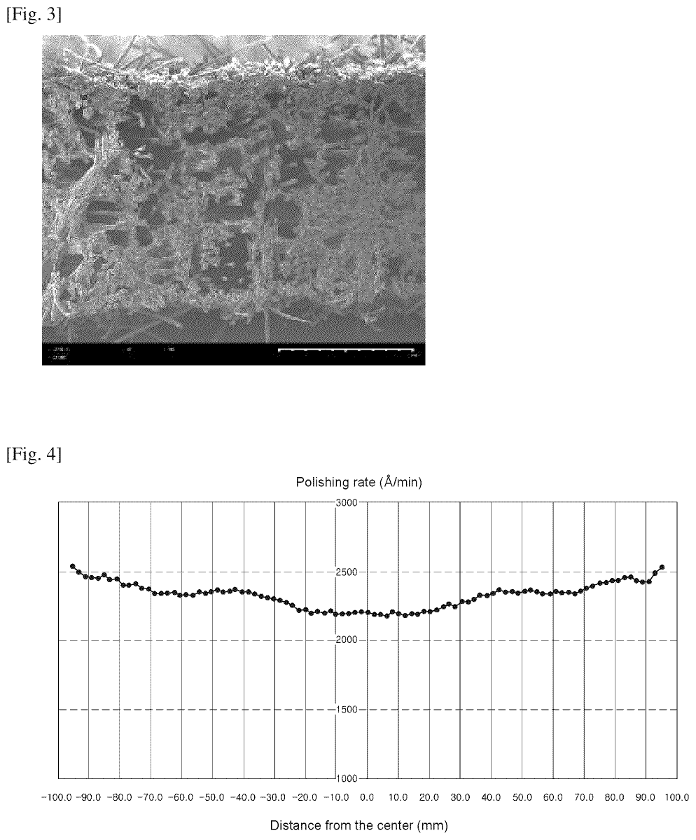

A polyester-based fiber nonwoven fabric was impregnated with a polyurethane resin and dried at 140° C. for 10 minutes to prepare a nonwoven fabric layer with a thickness of about 1.30 mm, thereby preparing a sub-pad having a single structure of the nonwoven fabric layer. Then, both sides of the nonwoven fabric layer were subjected to sanding treatment. FIG. 3 is a scanning electron microscope (SEM) image of a cross-section of the sub-pad in Comparative Example 2.

### (3) Preparation of a Polishing Pad

A polishing pad (total thickness: 3.32 mm) was prepared in the same manner as in Example 1.

### Physical Properties of the Sub-pads

### Test Example 1: Hardness

The sub-pads prepared in Example 1 and Comparative Examples 1 and 2 were each measured for hardness. Specifically, each sub-pad was cut to a length of 5 cm and a width of 5 cm and stored at 25° C. for 12 hours. A hardness meter was used to measure the Shore D hardness thereof.

### Test Example 2: Compressibility

The sub-pads prepared in Example 1 and Comparative Examples 1 and 2 were each measured for compressibility. Specifically, each sub-pad was cut to a length of 5 cm and a width of 5 cm, and a weight of 85 g was placed thereon for 30 seconds to measure the thickness (A) using a dial thickness gauge (Yasuda, 129-E) device. An additional weight of 800 g (a weight of 85 g and a weight of 800 g together) was placed thereon for 3 minutes to measure the thickness (B). The compressibility was then calculated according to the following Mathematical Equation 3.

$$Compressibility ( \% ) = [ ( A - B ) / A ] \times 100 \qquad [ Mathematical Equation 3 ]$$

### Test Example 3: Density

The sub-pads prepared in Example 1 and Comparative Examples 1 and 2 were each measured for density according to ASTM D1622.

### Test Example 4: Compressive Elasticity

The sub-pads prepared in Example 1 and Comparative Examples 1 and 2 were each measured for compressive elasticity. Specifically, each sub-pad was cut to a length of 5 cm and a width of 5 cm, and a weight of 85 g was placed thereon for 30 seconds to measure the thickness (A) using a dial thickness gauge (Yasuda, 129-E) device. An additional weight of 800 g (a weight of 85 g and a weight of 800 g together) was placed thereon for 3 minutes, the weight of 800 g was removed, and it was then left to stand for 1 minute to measure the thickness (C). The compressive elasticity was calculated according to the following Mathematical Equation 4.

$$Compressibility elasticity ( \% ) = [ C / A ] \times 100 \qquad [ Mathematical Equation 4 ]$$

### Physical Properties of the Polishing Pads

### Test Example 5: Polishing Rate (Removal Rate)

The polishing pads of Example 1 and Comparative Examples 1 and 2 were each fixed to the platen of CMP equipment, and a silicon wafer (diameter 300 mm) was set with the silicon oxide layer thereof facing downward. Then, a CMP process was carried out to measure the polishing rate.

Specifically, the silicon oxide layer was polished under a polishing load of 4.0 psi while the platen was rotated at a speed of 150 rpm for 60 seconds and a calcined ceria slurry and a silica slurry were supplied onto the polishing pad at a rate of 250 ml/minute. Upon completion of the polishing, the silicon wafer was detached from the carrier, mounted in a spin dryer, washed with deionized water, and then dried for 15 seconds with nitrogen. The difference in the thickness of the silicon oxide layer in the dried silicon wafer before and after the polishing was measured using a spectral reflectometer-type thickness measuring instrument (model: SI-F80R, manufacturer: Keyence). The polishing rate was calculated according to the following Mathematical Equation 1.

$$Polishing rate ( \mathring{A} / minute ) = difference in thickness before and after polishing ( \mathring{A} ) / polishing time ( minute ) \qquad [ Mathematical Equation l ]$$

In addition, the slope between distances of 85 mm and 95 mm from the center of the wafer in the polishing rate profile obtained through the measurement of the polishing rate.

### Test Example 6: Within-wafer Non-uniformity

The polishing pads of Example 1 and Comparative Examples 1 and 2 were each fixed to the platen of CMP equipment, and a silicon wafer (diameter 300 mm) was set with the silicon oxide layer thereof facing downward. Then, a CMP process was carried out to measure the within-wafer non-uniformity.

Specifically, polishing was carried out in the same manner as in Test Example 5. The in-plane film thickness of the wafer was measured at 98 points, and the within-wafer non-uniformity (WIWNU) within the wafer was measured according to the following Mathematical Equation 2.

$$Within - wafer non - uniformity ( WIWNU ) ( \% ) = ( standard deviation of polished thickness ( \mathring{A} ) / average polished thickness ( \mathring{A} ) ) \times 100 ( \% ) \qquad [ Mathematical Equation 2 ]$$

TABLE 1

| | | Ex. 1 | C. Ex. 1 | C. Ex. 2 |
|---|---|---|---|---|
| Sub-pad | Thickness (mm) | 1.53 | 0.63 | 1.30 |
| | Hardness (Shore D) | 70.7 | 75.9 | 72 |
| | Compressibility (%) | 8.9 | 8.9 | 9.4 |
| | Density (g/cm³) | 0.35 | 0.62 | 0.34 |
| | Compressive elasticity | 80.3 | 93.0 | 80.3 |
| | (%) | | | |
| Polish- | R₈₅ (Å/min) | 2,459 | 1,943 | 2,213 |
| ing pad | R₉₅ (Å/min) | 2,532 | 1,587 | 2,101 |
| | Avg. polishing rate (Å/ | 2,301 | 2,000 | 2,072 |
| | min) | | | |
| | Slope | 7.3989 | −30.948 | −20.311 |
| | Within-wafer non- | 4.0 | 8.3 | 5.7 |
| | uniformity (%) | | | |

As can be seen from Table 1 above, in the polishing pad according to Example 1, the polishing rate at a distance of 95 mm from the center of the wafer in the polishing rate profile in the CMP process for a silicon oxide layer was greater than the polishing rate at a distance of 85 mm from the center of the wafer. As a result, both the polishing rate and polishing flatness were excellent.

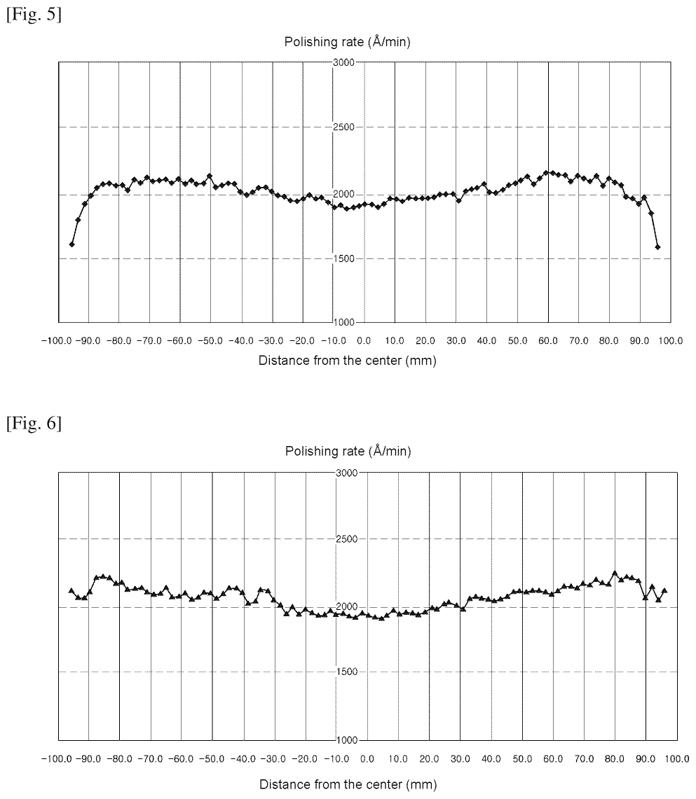

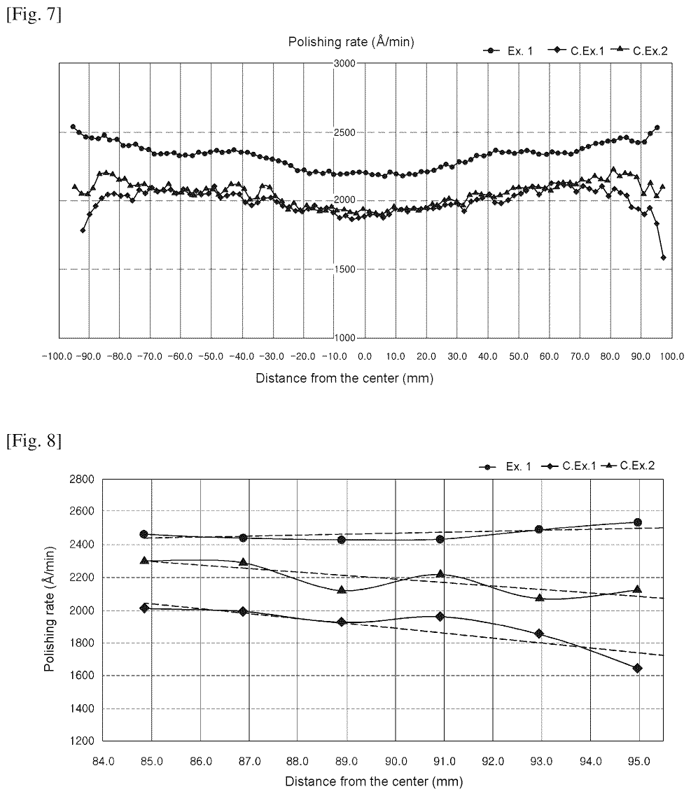

More specifically, in Comparative Examples 1 and 2, in which a sub-pad composed of a single layer of a suede layer or a nonwoven fabric layer was adopted as in the prior art, the slope between distances of 85 mm and 95 mm from the center of the wafer in the polishing rate profile in the CMP process for a silicon oxide layer had a negative value. In contrast, in the polishing pad of Example 1, in which a sub-pad composed of a dual structure of a nonwoven fabric layer and a suede layer was adopted, the average slope between distances of 85 mm and 95 mm from the center of the wafer in the polishing rate profile in the CMP process for a silicon oxide layer had a positive value, indicating a different trend in the polishing rate profile characteristics. In particular, in Comparative Examples 1 and 2, the slope was negative at a large value of about −30.948 and −20.311, whereas Example 1 had a positive slope at a value of about 7.3989. The latter showed a small change in the polishing rate at the edge, indicating excellent polishing uniformity, as compared with Comparative Examples 1 and 2 in which the polishing rate at the edge was steeply decreased (see FIGS. 4 to 8).

In addition, since the sub-pad of Example 1 had a low density relative to the thickness as compared with the sub-pads of Comparative Examples 1 and 2, the polishing rate was evenly distributed with respect to the distance from the center of the wafer in the polishing rate profile in the CMP process, resulting in excellent polishing flatness.

1. A polishing pad, which comprises a top-pad that is brought into contact with a wafer to perform polishing and a sub-pad that is located on one side of the top-pad, wherein the following Relationship 1 is satisfied:
$$R {R}_{85} < R {R}_{95} \qquad [ Relationship 1 ]$$
in Relationship 1, RR₈₅ is the polishing rate (Å/minute) at a distance of 85 mm from the center of the wafer in the polishing rate profile in a CMP process for a silicon oxide layer; and RR₉₅ is the polishing rate (Å/minute) at a distance of 95 mm from the center of the wafer in the polishing rate profile in a CMP process for a silicon oxide layer.

2. The polishing pad of claim 1, wherein the average slope between distances of 85 mm and 95 mm from the center of the wafer in the polishing rate profile in a CMP process for a silicon oxide layer has a positive value.

3. The polishing pad of claim 1, wherein the average slope between distances of 85 mm and 95 mm from the center of the wafer in the polishing rate profile in a CMP process for a silicon oxide layer is 0.5 or more.

4. The polishing pad of claim 1, wherein the average slope between distances of 85 mm and 95 mm from the center of the wafer in the polishing rate profile in a CMP process for a silicon oxide layer is 0.5 to 15.

5. The polishing pad of claim 1, wherein the polishing rate difference (ARR) according to the following Relationship 2 is 200 Å/minute or less:
$$Δ RR = R {R}_{95} - R {R}_{85} \qquad [ Relationship 2 ]$$
in Relationship 2, RR₈₅ is the polishing rate (Å/minute) at a distance of 85 mm from the center of the wafer in the polishing rate profile in a CMP process for a silicon oxide layer; and RR₉₅ is the polishing rate (Å/minute) at a distance of 95 mm from the center of the wafer in the polishing rate profile in a CMP process for a silicon oxide layer.

6. The polishing pad of claim 1, wherein, when the silicon oxide layer of a silicon wafer is polished with a ceria slurry using the polishing pad, the average polishing rate according to the following Mathematical Equation 1 is 2,100 Å/minute to 3,500 Å/minute:
$$Average polishing rate ( \mathring{A} / minute ) = difference in thickness before and after polishing ( \mathring{A} ) / polishing time ( minute ) \qquad [ Mathematical Equation l ]$$

7. The polishing pad of claim 1, wherein the polishing pad has a within-wafer non-uniformity (WIWNU) of 10% or less for oxides.

8. The polishing pad of claim 1, wherein the sub-pad comprises a nonwoven fabric layer and a suede layer.

9. The polishing pad of claim 8, wherein the suede layer is located on one side of the top-pad.

10. The polishing pad of claim 8, wherein the nonwoven fabric layer is a nonwoven fabric layer impregnated with a resin.

11. The polishing pad of claim 10, wherein the nonwoven fabric layer is a fibrous nonwoven fabric layer comprising at least one fiber selected from the group consisting of a polyester fiber, a polyamide fiber, a polypropylene fiber, and a polyethylene fiber.

12. The polishing pad of claim 10, wherein the resin impregnated in the nonwoven fabric layer comprises at least one resin selected from the group consisting of a polyurethane resin, a polybutadiene resin, a styrene-butadiene copolymer resin, a styrene-butadiene-styrene copolymer resin, an acrylonitrile-butadiene copolymer resin, a styrene-ethylene-butadiene-styrene copolymer resin, a silicone rubber resin, a polyester-based elastomer resin, and a polyamide-based elastomer resin.

13. The polishing pad of claim 8, wherein the ratio of thicknesses of the nonwoven fabric layer and the suede layer is 1:0.5 to 2.

14. The polishing pad of claim 1, wherein the sub-pad has:
a thickness of 0.5 mm to 2.5 mm,
a hardness of 60 Shore D to 90 Shore D,
a compressibility of 5% to 15%,
a density of 0.25 g/cm3 to 0.7 g/cm³, and
a compressive elasticity of 70% to 90%.

15. The polishing pad of claim 1, wherein the top-pad has:
a hardness of 50 Shore D to 65 Shore D,
a specific gravity of 0.6 g/cm³ to 0.9 g/cm³,
a tensile strength of 15 N/mm² to 25 N/mm², and
an elongation of 90% to 130%.

16. The polishing pad of claim 1, wherein the top-pad comprises a polishing layer comprising a polyurethane-based resin, and the polishing layer comprises a urethane-based prepolymer, a foaming agent, and a curing agent.

17. The polishing pad of claim 16, wherein the polishing layer has:
a thickness of 0.8 mm to 5 mm,
a specific gravity of 0.6 g/cm³ to 0.9 g/cm³,
a hardness of 30 Shore D to 80 Shore D,
a tensile strength of 5 N/mm² to 30 N/mm², and
an elongation of 50% to 300%.

18. A process for preparing a polishing pad, which comprises:
(1) preparing a top-pad using a top-pad composition comprising a urethane-based prepolymer, a foaming agent, and a curing agent;
(2) preparing a sub-pad comprising a nonwoven fabric layer and a suede layer; and
(3) combining the top-pad and the sub-pad to prepare a polishing pad,
wherein the polishing pad satisfies the following Relationship 1:
$$R {R}_{85} < R {R}_{95} \qquad [ Relationship 1 ]$$
in Relationship 1, RR₈₅ is the polishing rate (Å/minute) at a distance of 85 mm from the center of the wafer in the polishing rate profile in a CMP process for a silicon oxide layer; and RR₉₅ is the polishing rate (Å/minute) at a distance of 95 mm from the center of the wafer in the polishing rate profile in a CMP process for a silicon oxide layer.

19. The process for preparing a polishing pad of claim 18, wherein step (2) comprises impregnating a nonwoven fabric with a resin to prepare a nonwoven fabric layer; and casting a resin on one side of the nonwoven fabric layer to form a suede layer.

20. A process for preparing a semiconductor device, which comprises polishing the surface of a semiconductor substrate using the polishing pad of claim 1.
